(19) United States
(12) Patent Application Publication
(10) Pub. No.: US 2026/0037689 A1
(43) Pub. Date: Feb. 5, 2026

(54) METHOD FOR SIMULATED 3D VIDEO REPLAY OF WORKFLOWS BASED ON DEVICE DATA

(71) Applicant: Baxter Medical Systems GmbH + Co. KG, Saalfeld (DE)

(72) Inventor: Daniel Chase Shirley, Raleigh, NC (US)

(73) Assignee: Baxter Medical Systems GmbH + Co. KG, Saalfeld (DE)

(21) Appl. No.: 19/283,367

(22) Filed: Jul. 29, 2025

Related U.S. Application Data
(60) Provisional application No. 63/677,075, filed on Jul. 30, 2024.

(51) Int. Cl. G06F 30/20

(52) U.S. Cl. CPC G06F 30/20

(57) ABSTRACT

A visual recreation system of visually generating a recreation of a medical incident associated with a patient. The system includes a memory and a processor. The memory includes instructions that, when carried out by the processor, cause the processor to receive, from one or more sensors, a location information and a time information of the medical incident. The instructions further cause the processor to generate a visual simulation of the medical incident including an avatar of the patient and a visual reconstruction of a medical environment based on the location information and the time information of the medical incident.

### CROSS-REFERENCE TO RELATED APPLICATION

This application claims priority under U.S.C. § 119(e) to U.S. Provisional Application No. 63/677,075 filed on Jul. 30, 2024, entitled “A METHOD FOR SIMULATED 3D VIDEO REPLAY OF WORKFLOWS BASED ON DEVICE DATA,” the disclosure of which is hereby incorporated by reference in its entirety.

### FIELD OF THE DISCLOSURE

The present disclosure generally relates to systems, methods, and programs for visually generating a recreation of a medical incident associated with a patient within a medical environment.

### BACKGROUND

In a medical environment, where caregivers are tasked with the care of a patient, when a safety event occurs, quality representatives are tasked with documenting the event, identifying the root cause of the event, and providing recommendations for how to make improvements. Depending on the safety event and findings of the quality representatives, the recommended course can include a recommendation for a change in staff, internal process changes, or the implementation of technology to prevent that safety event from happening again. Currently, tools available to these quality representatives make it difficult to paint a complete picture of the safety event. Quality representatives usually investigate the safety event through device logs and qualitative interviews of staff, which rely heavily on recollection. As a result, quality representatives often struggle to piece all the information surrounding the safety event together leaving room for assumptions and inaccuracies.

Accordingly, the present disclosure generally relates to systems, methods, and programs for visually generating a recreation of a medical incident associated with a patient within a medical environment. In this manner, the disclosure provides tools to quality representatives or other investigatory bodies to obtain information surrounding a medical incident in a complete and easy to consume format.

### SUMMARY OF THE DISCLOSURE

According to one aspect of the present disclosure, a computer program product includes a non-transitory computer-readable storage medium readable by one or more processing circuits and storing instructions for execution by one or more processors for performing a method of visually generating a recreation of a medical incident associated with a patient based on feedback from one or more sensors. The method includes receiving, from the one or more sensors, location information and time information of the medical incident, and generating a visual simulation of the medical incident based on the location information and the time information of the medical incident.

According to another aspect of the present disclosure, a visual recreation system of visually generating a recreation of a medical incident associated with a patient is provided. The system includes a memory and a processor. The memory includes instructions that, when carried out by the processor, cause the processor to receive, from one or more sensors, location information and time information of the medical incident. The instructions further cause the processor to generate a visual simulation of the medical incident including an avatar of the patient and a visual reconstruction of a medical environment based on the location information and the time information of the medical incident.

According to yet another aspect of the present disclosure, a method of visually generating a recreation of a medical incident associated with a patient is provided. The method includes receiving, from one or more sensors, location information and time information of the medical incident, and generating an avatar of the patient during the medical incident and a visual reconstruction of a medical environment during the medical incident based on the location information and the time information of the medical incident.

These and other features, advantages, and objects of the present disclosure will be further understood and appreciated by those skilled in the art by reference to the following specification, claims, and appended drawings.

### BRIEF DESCRIPTION OF THE DRAWINGS

In the drawings:

FIG. 1 is a side elevational view of a workflow monitoring system within a medical environment, according to an aspect of the present disclosure;

FIG. 2 is a top, plan view of a workflow monitoring system within a medical environment, according to an aspect of the present disclosure;

FIG. 3 is a visual reconstruction of a medical environment surrounding a medical incident from a top-down perspective that includes avatars of caregivers and a patient, according to an aspect of the present disclosure;

FIG. 4 is a visual reconstruction of a medical environment surrounding a medical incident from an isometric perspective that includes avatars of caregivers and a patient, according to an aspect of the present disclosure;

FIG. 5 is a visual reconstruction of areas of interest in a medical environment surrounding a medical incident from a schematic perspective that includes avatars of caregivers and a patient, according to an aspect of the present disclosure;

FIG. 6 is a visual reconstruction of a medical environment surrounding a medical incident from a first person perspective that includes a patient, according to an aspect of the present disclosure;

FIG. 7A is a front plan view of a mobile device with a display that a visual reconstruction of a medical environment surrounding a medical incident is generated on, according to an aspect of the present disclosure;

FIG. 7B is a front plan view of a computing device with a display that a visual reconstruction of a medical environment surrounding a medical incident is generated on, according to an aspect of the present disclosure;

FIG. 7C is a front perspective view of a headset device with a display that a visual reconstruction of a medical environment surrounding a medical incident is generated on, according to an aspect of the present disclosure;

FIG. 8 is a schematic view of a control system of a workflow monitoring system, according to an aspect of the present disclosure;

FIG. 9 is a top plan view of a computer program that creates a visual reconstruction of a medical environment surrounding a medical incident, according to an aspect of the present disclosure; and

FIG. 10 is a flow chart of a method of utilizing a workflow monitoring system to create a visual reconstruction of a medical environment surrounding a medical incident, according to an aspect of the present disclosure.

### DETAILED DESCRIPTION

The present illustrated embodiments reside primarily in combinations of method steps, systems, devices, and apparatus components related to systems, methods, and programs for visually generating a recreation of a medical incident associated with a patient within a medical environment. Accordingly, the apparatus components and method steps have been represented, where appropriate, by conventional symbols in the drawings, showing only those specific details that are pertinent to understanding the embodiments of the present disclosure so as not to obscure the disclosure with details that will be readily apparent to those of ordinary skill in the art having the benefit of the description herein. Further, like numerals in the description and drawings represent like elements.

The specific structures and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

The terms “including,” “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises a . . . ” does not, without more constraints, preclude the existence of additional identical elements in the process, method, article, or apparatus that comprises the element.

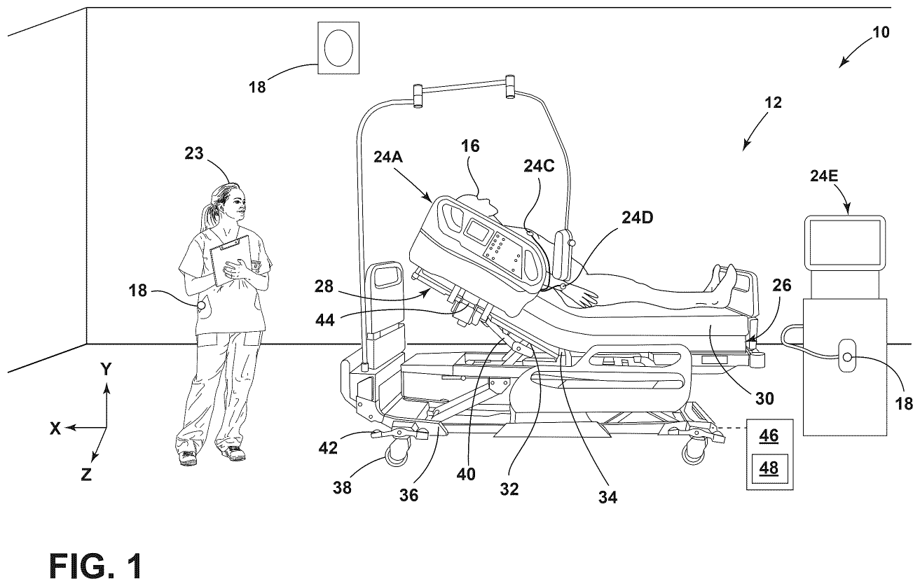

Referring initially to FIGS. 1-6, reference numeral 10 generally designates a visual recreation system for a medical environment 12. The system 10 may include several components configured to visually generate a recreation of a medical incident 14 associated with a patient 16. The system 10 includes a control system 100 that may include a processor 104 and a memory 106. The memory 106 includes instructions that, when carried out by the processor 104, cause the processor 104 to receive, from the one or more sensors 18, a location information and a time information of the medical incident 14. The instructions further cause the processor 104 to generate a visual simulation 20 of the medical incident including an avatar of the patient (“P”) and a visual reconstruction 22 of a medical environment 12 based on the location information and the time information of the medical incident 14.

Over the course of the patient's 16 stay or visit to the medical environment 12, sometimes medical incidents 14 occur. These medical incidents 14 may result in any type of negative health outcomes to the patient 16 and be related or unrelated to care the patient 16 has received in the medical environment 12. For example, the patient 16 may fall over the course of the stay or visit to the medical environment 12, the patient 16 may become dehydrated, develop bedsores, receive inappropriate pharmaceutical or physical therapy regiments, have other negative health outcomes related to care received or lack of care received, and/or the like. In some cases, medical incidents are entirely unavoidable as a patient P may fall during an ordinary course of the visitation. Regardless of the cause, after the medical event, it is important that the patient 16 quickly receive care from one or more caregivers 23 that are expected to be ready, willing, and able to assist in the event of the medical condition. In this manner, the visual simulation 20 of the medical incident 14 allows a user, such as a quality representative or other investigatory body, to review events leading up to, during, and after the medical incident 14. Accordingly, the visual simulation 20 of the medical incident 14 can be utilized to discover the root causes of the medical incident 14 and facilitate establishing preventative and remedial processes and workflow strategies for medical care.

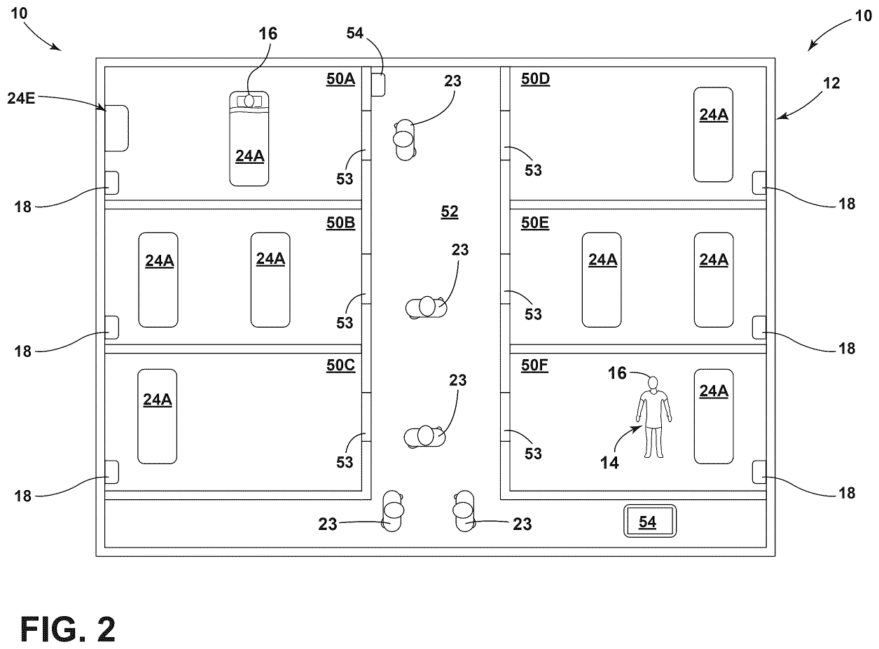

With reference now to FIGS. 1-2, the medical environment 12 may include a medical facility (e.g., a hospital), and emergency center, a medical campus with numerous buildings, the patient's 16 home if a home-visit health service is utilized, and/or the like. Generally speaking, the medical environment 12 may be any location that employs one or more caregivers 23 with different responsibilities for monitoring and providing care to the patient 16. Oftentimes, the medical environment 12 may further have visitors and other staff members (e.g., janitors, delivery personnel) who do not have direct patient care responsibilities. It should be appreciated that the system 10 may also monitor (e.g., with the one or more sensors 18) these additional persons within the medical environment 12. In this manner, the workflow and conditions regarding personnel within the medical environment 12 surrounding the medical incident 14 can be monitored and, in some embodiments, recreated in the visual simulation 20. In this manner, preventative and remedial processes and workflow strategies for medical care can be based, at least in part, on the medical environment. In some implementations, the type of medical environment 12 associated with a medical incident may be categorized (e.g., hospital, campus, home-health service) to permit the quality representatives to formulate preventative and remedial processes and workflow strategies for different types of medical environments 12. Further, the different categorizations of the medical environments 12 may be associated with different visual simulations 20 (e.g., the visual simulation 20 may appear to be in a residential building or hospital facility) to improve visualization.

The medical environment 12 often employs one or more medical devices 24A-24N that provide direct care (e.g., administer drugs or fluids), monitor the patient's 16 vitals, support the patient 16, and/or the like. It should be appreciated that the system 10 may also monitor (e.g., with the one or more sensors 18) and/or otherwise receive information from the one or more medical devices 24A-24N. For example, the system 10 may also monitor (e.g., with the one or more sensors 18) and/or otherwise receive information on the status (e.g., settings) of the medical devices 24A-24N, administration rates (e.g., of drugs or fluids), measurements of the patient's 16 vitals, and/or the like. In this manner, medical devices 24A-24N within the medical environment 12 surrounding the medical incident 14 can be monitored and, in some embodiments, recreated in the reconstruction 22 of a medical environment 12.

With reference now particularly to FIG. 1, these medical devices 24A-24N may include a patient table 24A with a variety of settings. The patient table or bed 24A may include a patient support mattress 26 and a mattress support frame 28 that supports and positions the patient support mattress 26. In some embodiments, the patient support mattress 26 includes one or more (e.g., two, three, four, five, or six) pads 30 and the mattress support frame 28 may include one or more sub-support frames 32 (e.g., two, three, four, five, or six). The sub-support frames 32 may be operably coupled by linkages 34 that permit articulation between adjacent sub-support frames 32 to position a patient in varying orientations. In some embodiments, the one or more pads 30 may be integrally (e.g., permanently or with additional tools and/or fasteners) connected with the sub-support frames 32 such that they cannot be removed after assembly. In other embodiments, the one or more pads 30 may be non-integrally (e.g., removable) connected with the sub-support frames 32 such that they can be connected to and removed from the sub-support frames 32. It should also be appreciated that select pads 30 may be integrally connected and select pads 30 may be non-integrally connected within the patient table 24A. The non-integral connection may be beneficial to remove the one or more pads 30 for cleaning, replacement, or servicing.

The patient table 24A may also include a base frame 36 that may include a plurality of caster wheels 38 that allow the patient table 24A to roll between different locations (e.g., along an X-axis and a Z-axis). An actuating arm 40 is configured to adjust the mattress support frame 28 (e.g., via linkages 34). The actuating arm 40 may be adjustable between a variety of positions to suit the needs of a caregiver 23 by allowing the patient bed 24A to adjust between lying positions and sitting positions for the patient 16. More particularly, the actuating arm 40 may include and be driven by driving mechanism 42 (e.g., a driven-gear mechanism). In some embodiments, the actuating arm 40 is located centrally over the base frame 36 between the caster wheels 38 and centrally under the mattress support frame 28, such that a patient's center of mass is substantially aligned therewith along the Y-axis. In some embodiments, a central wheel (not shown) may be located under the actuating arm 40 to facilitate movement. The central wheel may be driven via a motor, and/or the like, and may be moveable between an operating (i.e., rolling) position and a stowed position.

With continued reference to FIG. 1, the patient table 24A may include a user interface 44 for selecting the various settings, such as the actuating arm 40 positioning, locking, unlocking, and moving the caster wheels 38, and/or the like. The patient table 24A may have a power system 46 such as a wall outlet plug, a battery 48, or a hybrid combination of both that powers the user interface 44 and the operation of the various settings. In addition, it should be appreciated that the patient table 24A may include additional settings and features. For example, the patient table 24A may include, be operably connected, or separate from various other medical devices 24B-24N. In some embodiments, some or all of the other medical devices 24B-24N may be operable through the user interface 44 and powered by the battery 48. In some embodiments, some or all of the other medical devices 24B-24N may be operable through independent and separate user interfaces and power supplies (e.g., wired and/or battery).

With reference now to both FIGS. 1 and 2, the other medical devices 24B-24N may include a weight sensor 24B. The weight sensor 24B may be located in and/or generally aligned with the actuating arm 40 along the Y-axis. The weight sensor 24B may selectively display a weight of the patient 16 on the user interface 44. The weight sensor 24B may be powered by the battery 48. In some embodiments, the other medical devices 24B-24N may include a vitals monitor 24C. The vitals monitor 24C may be directly connected to and/or integrated with components of the patient table 24A. The vitals monitor 24C may selectively monitor various vitals of the patient 16. For example, the vitals may include a heart rate, oxygen level, blood pressure, respiration rate, and temperature. The measurement of the vitals may be selectively generated on the user interface 44 (e.g., a user interface display). The measurement and display of the vitals may be controlled by operating the various settings on the user interface 44. The vitals monitor 24C may be powered by the battery 48.

In some embodiments, the other medical devices 24B-24N may include a fluid delivery system 24D. The fluid delivery system 24D may be directly connected to and/or integrated with components of the patient table 24A. The fluid delivery system 24D may selectively provide fluids (e.g., water, electrolytes, etc.) to the patient 16. A measurement of the fluid exchange may be generated on the user interface 44 and/or a different user interface. The rate and display of the fluid exchange may be controlled by operating the various settings on the user interface 44. The fluid delivery system 24D may be powered by the battery 48 and/or an independent power source. In some embodiments, the other medical devices 24B-24N may include a drug delivery system 24E. The drug delivery system 24E may be directly connected to and/or integrated with components of the patient table 24A. The drug delivery system 24E may selectively provide medicines, anesthetics, and/or the like to the patient 16. A measurement of the medicine delivery provided to the patient 16 may be generated (e.g., monitored, transmitted, and visualized) on the user interface 44 and/or on a different display. The rate of delivery and display of the fluid exchange may be controlled by operating the various settings on the user interface 44 and/or a different user interface. The drug delivery system 24E may be powered by the battery 48 and/or an independent power source. It should be appreciated that the example medical devices 24A-24E are exemplary in nature and that other medical devices 24N may be used within the adaptive healthcare system 10. In some embodiments, each medical device 24A-24N may be associated with a unique device identifier, such that the system 10 can monitor the use of each medical device 24A-24N individually. In some embodiments, each medical device 24B-24N includes a power system like the power system 46 in the patient table 24A.

With continued reference to FIGS. 1 and 2, in some embodiments, each caregiver 23, the patient 16, and the medical device 24A-24N (or grouping of medical devices 24B-24N integrated with the patient table 24A) may include a location identifier (e.g., one or more sensors 18). For example, the one or more sensors 18 may include a variety of proximity sensors, such as Radio Frequency (“RF”) sensors, proximity sensors, positional sensors, and/or the like. The one or more sensors 18 may further or alternatively include optical sensors, such as cameras located in and around the medical environment 12, 3D vision systems (e.g., structured light), and/or the like. The one or more sensors 18 may further or alternatively utilize Global Positioning System (“GPS”) receivers, mobile network receivers, wi-fi receivers, geo-fencing structures, and or the like. The one or more sensors 18 may be located within and/or on structures of the medical environment 12 such as walls, ceilings, floors, and/or the like. The one or more sensors 18 may further or alternatively be located in wearable devices, mobile devices (e.g., mobile phones assigned to a caregiver), and/or the like. The one or more sensors 18 may be utilized for mapping the medical environment 12 prior to generating the visual reconstruction 22 of a medical environment 12. In addition or alternatively to utilizing the one or more sensors 18, the medical environment 12 may be pre-modeled and/or otherwise saved and utilized when generating the visual reconstruction 22 of a medical environment 12.

With reference now to FIG. 2, the medical environment 12 may include a plurality of rooms 50A-50F, with the medical incident 14 in room 50F (e.g., the patient 16 falling). Each room 50A-50F may have different shapes, medical devices 24A-24N, patient 16, and caregivers 23. The rooms 50A-50F may be connected by a hallway 52 and accessible via doors 53. The system 10 may be utilized across the medical environment 12 (e.g., multiple or all of the rooms 50A-50F and the hallway 52). Accordingly, it should be appreciated that the visual simulation 20 of the medical incident and the visual reconstruction 22 of a medical environment 12 may or may not be limited to individual rooms 50A-50F in which the associated medical incident 14 occurred. More particularly, a user of the system 10 may select an overview of several rooms 50A-50F, a single room 50A-50F, or rooms of interest 50A-50F. As will be appreciated with further reading, the system 10 may select rooms of interest 50A-50F based on a time during the medical incident 14 or a time period surrounding the medical incident 14 that tracks the movement of the patient 16 and one or more caregivers 23 related to the incident based on responsibilities, proximity, and/or the like. In this manner, the visual simulation 20 of the medical incident and the visual reconstruction 22 of a medical environment 12 may be specific to the room 50A-50F where the medical incident 14 occurred, each room 50A-50F (e.g., the room 50A-50F where the medical incident 14 occurred and rooms 50A-50F proximate), or rooms of interest 50A-50F to provide a comprehensive overview to workflow leading to the medical incident 14. In some embodiments, specific rooms 50A-50F are scaled, whereas rooms of interest 50A-50F are enlarged. In some embodiments, the visual reconstruction 22 of a medical environment 12 is generated to a relative scale of the dimensions of the medical environment 12. In some embodiments, the rooms 50A-50F in the visual simulation 20 may include room indicators (“RI”) (e.g., room numbers, patient names, room types, and/or the like) that overlay the visual reconstruction 22. The room indicators RI may be automatically generated and/or selectable by a user.

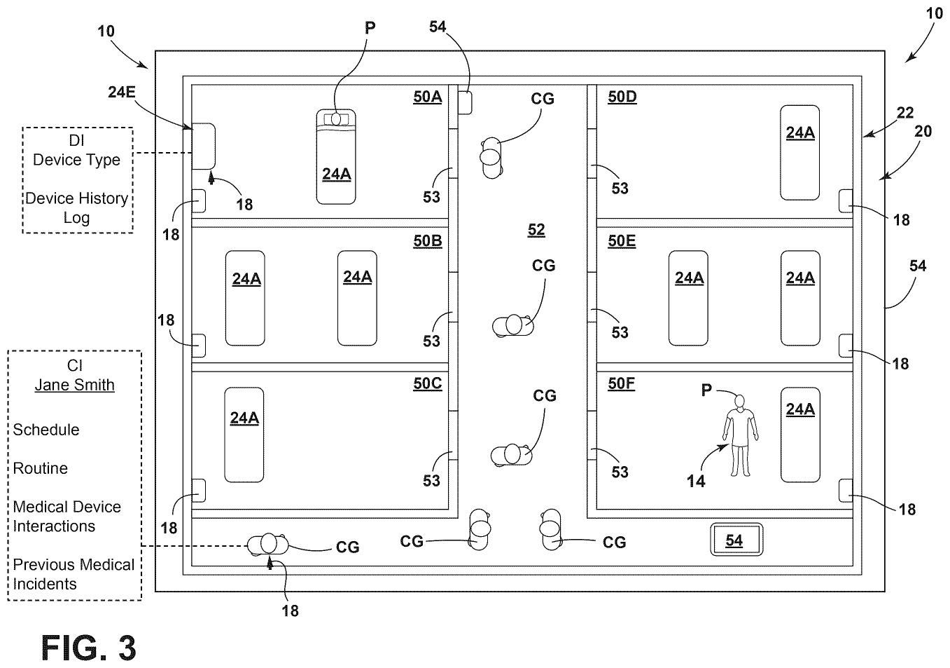

With reference now to FIGS. 3-6, the system 10 may be configured to generate the visual simulation 20 in multiple formats. Generally speaking, the visual simulation 20 of the medical incident may include the visual reconstruction 22 of a medical environment 12, the avatar of the patient P, one or more avatars of caregivers CG or other personnel within the medical environment 12, and device indicators (“DI”) of the medical devices 24A-24N. In some implementations, the medical environment 12 (e.g., the facility, building, or room) may be generated in the visual reconstruction 22 based on the template associated with the characterization of the medical environment 12. The device indicators DI may include information that automatically (e.g., by the system 10) or selectively (e.g., by input from a user) overlay the visual reconstruction 22. The device indicator DI may include the type of medical device 24A-24N, a log of caregivers 23 that used the medical device 24A-24N most recently and/or within a time period, a history of the usage of the medical device 24A-24N (e.g., status), and places (e.g., rooms 50A-50F) within the medical environment 12 that the medical device 24A-24N was located. Further, the device indicators DI may be automatically or selectively shown in the visual simulation 20 based on medical devices of interest. For example, the medical devices of interest may be classified by the medical devices 24A-24N associated (used by or for the patient 16, in close proximity to the patient 16, etc.) with the patient 16 during the medical incident 14 or a time period surrounding the medical incident 14. The medical devices of interest may further be classified by usage by a caregiver of interest within a time period surrounding the medical incident 14.

The visual simulation 20 of the medical incident and the visual reconstruction 22 of a medical environment 12 may be generated over a period of time surrounding the medical incident 14. For example, a user may select the period of time or the system 10 may automatically select the period of time, before, during, and/or after the medical incident 14 that is visually recreated. The visual simulation 20 of the medical incident 14 and the visual reconstruction 22 of a medical environment 12 may be played at a rate that the events happened in real time, fast-forwarded, or slowed down. The visual simulation 20 may also be automatically or selectively looped within the period of time.

Still referring to FIGS. 3-6, the system 10 may be configured to generate avatars of caregivers CG for each caregiver 23 or determine or otherwise select by a user, specific avatars of caregivers CG to generate (e.g., caregivers of interest). For example, caregivers 23 surrounding the medical incident 14 may be classified as a caregiver of interest, such as an assigned caregiver 23, a caregiver's 23 responsibilities relating to the patient P, a first-on-scene caregiver 23, a last-on-scene caregiver 23, a selected caregiver 23, and/or other criteria on a case-by-case basis. The assigned caregiver 23 may include the caregiver 23 specifically tasked with the care of the patient 16, such as making rounds, responding to alerts, responding to communications from the patient 16, and/or responding to communications from other personnel (e.g., other caregivers 23) on the topic of the patient 16. The first-on-scene caregiver 23 may include the caregiver 23 that first became aware of the medical incident 14 (e.g., visually or via communication from the patient 16). The last-on-scene caregiver 23 may include the caregiver that was last in contact with the patient 16 and/or one of the medical devices 24A-24N associated with the patient's 16 care. The selected caregiver 23 may be associated with an avatar of a caregiver CG selected by a user. Other criteria may include the caregiver 23 that was most proximate the patient 16 at the time of the medical incident 14, any of the caregivers 23 that communicated with the patient 16 within a period of time (e.g., 30 minutes or less, 20 minutes or less, 10 minutes or less, 5 minutes or less), or any of the caregivers 23 that entered the patient's assigned room 50A-50F and/or the room 50A-50F that the medical incident 14 occurred. The caregiver avatars CG may include caregiver identifiers “CI” that provide specific details about the caregivers 23 (e.g., name, employment position, responsibilities, shift details, movement paths, communications, interactions with medical devices 24A-24N, etc.) that overlay the visual reconstruction 22. The caregiver identifiers CI may be automatically generated and/or selectable by a user.

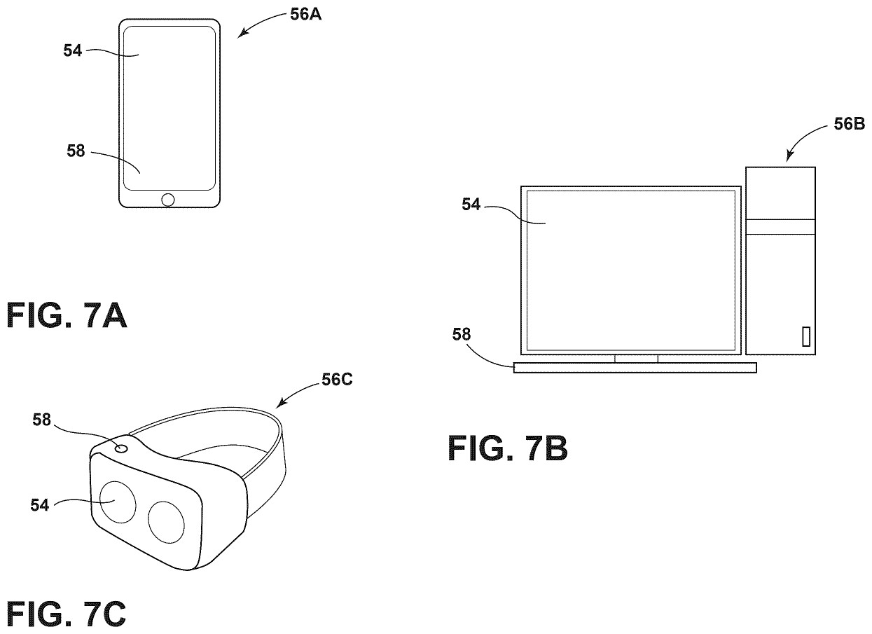

With reference now to FIG. 3, the visual simulation 20 is depicted on a display 54 of a device 56A-56C. As will be described in greater detail, the device 56A-56C may have a variety of constructions including at least those depicted in FIGS. 7A-7C. The visual simulation 20 is generated as a top-down perspective surrounding the patient 16 during the medical incident 14. The visual simulation 20 may include the visual reconstruction 22 of a medical environment 12, the avatar of the patient P, one or more avatars of caregivers CG or other personnel within the medical environment 12, caregiver identifiers CI, room indicators RI of the rooms 50A-50F, and device indicators DI of the medical devices 24A-24N. The top-down perspective of the visual reconstruction 22 of a medical environment 12 may be specific to the room 50A-50F where the medical incident 14 occurred, each room 50A-50F (e.g., the room 50A-50F where the medical incident 14 occurred and rooms 50A-50F proximate), or rooms of interest 50A-50F. In some embodiments, specific rooms 50A-50F are scaled, whereas rooms of interest 50A-50F are enlarged. In some embodiments, the visual reconstruction 22 of a medical environment 12 is generated to a relative scale of the dimensions of the medical environment 12. In some embodiments, a user may utilize a human-machine interface 58 to enlarge specific rooms 50A-50F or the system 10 may determine (e.g., via a determination through the control system 100) which rooms 50A-50F are of interest to scale. The top-down perspective may be beneficial to understanding the scale and obtaining an overview of one or more rooms 50A-50F within the medical environment 12. When rooms 50A-50F are located on more than one floor, the visual reconstruction 22 may display floors side-by-side or allow a user to select between floors to monitor the patient or caregiver 23 activities. When a floor is large and includes too many rooms 50A-50F to meaningfully monitor activities, only a region of the floor may be shown in the visual reconstruction 22 or the visual reconstruction 22 can be zoomed in and out.

The human-machine interface 58 may be shown on the visual simulation 20 of the display 54 depicted in FIG. 3 or otherwise controllable outside of the display 54 (e.g., a keyboard) and may include cursors, time controls, options to change views, the ability to select avatars of caregivers CG that are generated based on the caregiver of interest criteria or classifications, and the ability to select medical devices of interest based on the criteria described above. In this manner, a user may obtain information about one or more of the caregivers 23 by selecting the avatar of the caregiver CG to obtain the caregiver identifier CI details (e.g., name, employment position, responsibilities, shift details, movement paths, communications, interactions with medical devices 24A-24N), which may be overlayed (e.g., as text or graphics) on the visual reconstruction 22. In some embodiments, once generated, the caregiver identifier CI details may be generated as links that lead to additional information. For example, the caregiver identifier CI details related to interactions with the medical devices 24A-24N may be selected to highlight, zoom, and/or otherwise indicate that medical device 24A-24N within the visual simulation 20. In some embodiments, the system 10 may generate a visual indicia on or proximate the avatar of the caregiver 23 in a visual simulation 20 once that caregiver 23 becomes aware of the medical incident 14. For example, as the visual simulation 20 plays, once a caregiver becomes aware of the medical incident 14, the visual indicia may be implemented as a highlight of the avatar of the caregiver 23, an exclamation point over the avatar of the caregiver 23, changing the size of the avatar of the caregiver 23, or via other visual cues.

Likewise, the device indicator DI details may be generated based on the medical device of interest criteria or classifications. In this manner, a user may obtain information about one or more of the medical devices 24A-24N by selecting the device indicator DI to obtain the device indicator DI details (e.g., the type of medical device 24A-24N, a log of caregivers 23 that used the medical device 24A-24N most recently and/or within a time period, a history of locations of the medical device 24A-24N within the medical environment 12, and a history of the usage of the medical device 24A-24N (e.g., status), which may be overlayed (e.g., as text or graphics) on the visual reconstruction 22. In some embodiments, once generated, the device indicator DI details may be generated as links that lead to additional information. For example, the device indicator DI details related to interactions with the medical devices 24A-24N by specific caregivers 23 may be selected to highlight, zoom, and/or otherwise indicate the avatar of the caregiver 23 within the visual simulation 20.

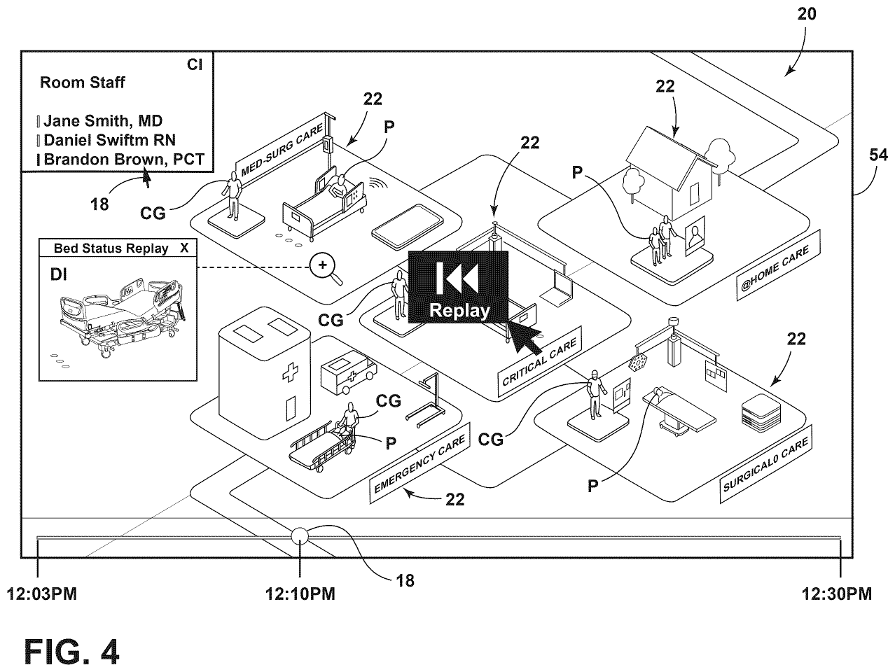

With reference now to FIG. 4, the visual simulation 20 is depicted on the display 54 of the device 56A-56C. The visual simulation 20 is generated as an isometric perspective surrounding the patient 16 during the medical incident 14. The visual simulation 20 may include the visual reconstruction 22 of a medical environment 12, the avatar of the patient P, one or more avatars of caregivers CG or other personnel within the medical environment 12, caregiver identifiers CI, room indicators RI of the rooms 50A-50F, and device indicators DI of the medical devices 24A-24N. The isometric perspective of the visual reconstruction 22 of a medical environment 12 may be specific to the room 50A-50F where the medical incident 14 occurred, each room 50A-50F (e.g., the room 50A-50F where the medical incident 14 occurred and rooms 50A-50F proximate), or rooms of interest 50A-50F. In some embodiments, specific rooms 50A-50F are scaled, whereas rooms of interest 50A-50F are enlarged. In some embodiments, the visual reconstruction 22 of a medical environment 12 is generated to a relative scale of the dimensions of the medical environment 12. In some embodiments, a user may utilize a human-machine interface 58 to enlarge specific rooms 50A-50F or the system 10 may determine (e.g., via a determination through the control system 100) which rooms 50A-50F are of interest to scale. The isometric perspective may be useful in situations where the medical environment 12 is on more than one floor, building, or location of a medical facility. In this manner, the isometric perspective may include discrete visual simulations 20 of specific rooms 50A-50F, floors, buildings, or locations in the medical facility linked by arrows or other indicia.

Similar to the top-down perspective, the human-machine interface 58 may be shown on the visual simulation 20 of the display 54 depicted in FIG. 4 or otherwise controllable outside of the display 54 (e.g., a keyboard) and may include cursors, time controls, options to change views, the ability to select avatars of caregivers CG that are generated based on the caregiver of interest criteria or classifications, and the ability to select medical devices of interest based on the criteria described above. In this manner, a user may obtain information about one or more of the caregivers 23 by selecting the avatar of the caregiver CG to obtain the caregiver identifier CI details (e.g., name, employment position, responsibilities, shift details, movement paths, communications, interactions with medical devices 24A-24N), which may be overlayed (e.g., as text or graphics) on the visual reconstruction 22. In some embodiments, once generated, the caregiver identifier CI details may be generated as links that lead to additional information. For example, the caregiver identifier CI details related to interactions with the medical devices 24A-24N may be selected to highlight, zoom, and/or otherwise indicate that medical device 24A-24N within the visual simulation 20. In some embodiments, the system 10 may generate the visual indicia on or proximate the avatar of the caregiver 23 in a visual simulation 20 once that caregiver 23 becomes aware of the medical incident 14. For example, as the visual simulation 20 plays, once a caregiver becomes aware of the medical incident 14, the visual indicia may be implemented as a highlight of the avatar of the caregiver 23, an exclamation point over the avatar of the caregiver 23, changing the size of the avatar of the caregiver 23, or via other visual cues.

The device indicator DI details may be generated based on the medical device of interest criteria or classifications. In this manner, a user may obtain information about one or more of the medical devices 24A-24N by selecting the device indicator DI to obtain the device indicator DI details (e.g., the type of medical device 24A-24N, a log of caregivers 23 that used the medical device 24A-24N most recently and/or within a time period, a history of locations of the medical device 24A-24N within the medical environment 12, and a history of the usage of the medical device 24A-24N (e.g., status), which may be overlayed (e.g., as text or graphics) on the visual reconstruction 22. In some embodiments, once generated, the device indicator DI details may be generated as links that lead to additional information. For example, the device indicator DI details related to interactions with the medical devices 24A-24N by specific caregivers 23 may be selected to highlight, zoom, and/or otherwise indicate the avatar of the caregiver 23 within the visual simulation 20.

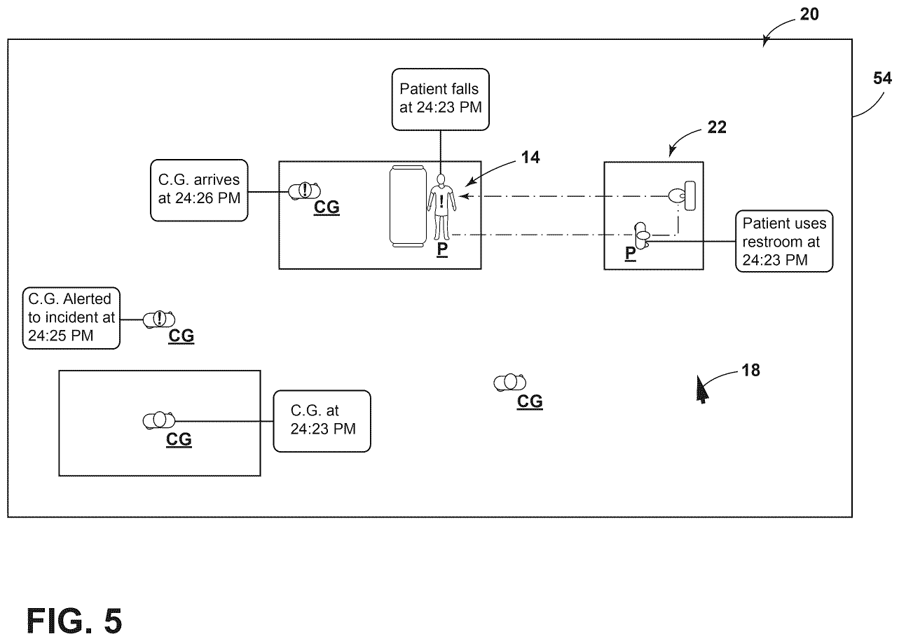

With reference now to FIG. 5, the visual simulation 20 is depicted on the display 54 of the device 56A-56C. The visual simulation 20 is generated as a top-down schematic perspective surrounding the patient 16 during the medical incident 14. As depicted, the visual simulation 20 may condensed and include the visual reconstruction 22 of a medical environment 12, the avatar of the patient P, one or more avatars of caregivers CG or other personnel within the medical environment 12, caregiver identifiers CI, room indicators RI of the rooms 50A-50F, and device indicators DI of the medical devices 24A-24N. The top-down schematic perspective may include graphics overlaying the visual simulation 20 illustrating travel paths (PH) of the avatars of the caregiver CG (e.g., caregivers of interest) and the avatar of the patient P. The top-down schematic perspective may further include graphics overlaying the visual simulation 20 illustrating summaries of activities, statuses, and locations, associated with the patient 16, the caregivers 23, and the medical devices 24A-24N. The visual reconstruction 22 of a medical environment 12 may be specific to rooms of interest 50A-50F and may not include hallways 52, doors 53, or other details of the medical environment. In some embodiments, the rooms of interest 50A-50F are each generated with identical shapes and sizes. In some embodiments, the rooms of interest 50A-50F are generated to a relative scale of the dimensions of the medical environment 12. In some embodiments, a user may utilize a human-machine interface 58 to enlarge specific rooms of interest 50A-50F or the system 10 may determine (e.g., via a determination through the control system 100) which rooms of interest 50A-50F to scale (e.g., shrink or enlarge). While FIG. 5 depicts the top-down schematic perspective, the schematic and condensing of the information in the visual simulation 20 may be applied to any of the other perspectives described herein (e.g., an isometric schematic view, a first-person-schematic view, etc.).

Similar to the top-down and isometric perspectives, the human-machine interface 58 may be shown on the visual simulation 20 of the display 54 depicted in FIG. 5 or otherwise controllable outside of the display 54 (e.g., a keyboard) and may include cursors, time controls, options to change views, the ability to select avatars of caregivers CG that are generated based on the caregiver of interest criteria or classifications, and the ability to select medical devices of interest based on the criteria described above. In this manner, a user may obtain information about one or more of the caregivers 23 by selecting the avatar of the caregiver CG to obtain the caregiver identifier CI details (e.g., name, employment position, responsibilities, shift details, movement paths, communications, interactions with medical devices 24A-24N), which may be overlayed (e.g., as text or graphics) on the visual reconstruction 22. In some embodiments, once generated, the caregiver identifier CI details may be generated as links that lead to additional information. For example, the caregiver identifier CI details related to interactions with the medical devices 24A-24N may be selected to highlight, zoom, and/or otherwise indicate that medical device 24A-24N within the visual simulation 20. In some embodiments, the system 10 may generate the visual indicia on or proximate the avatar of the caregiver 23 in a visual simulation 20 once that caregiver 23 becomes aware of the medical incident 14. For example, as the visual simulation 20 plays, once a caregiver becomes aware of the medical incident 14, the visual indicia may be implemented as a highlight of the avatar of the caregiver 23, an exclamation point over the avatar of the caregiver CG, changing the size of the avatar of the caregiver 23, or via other visual cues.

Likewise, the device indicator DI details may be generated based on the medical device of interest criteria or classifications. In this manner, a user may obtain information about one or more of the medical devices 24A-24N by selecting the device indicator DI to obtain the device indicator DI details (e.g., the type of medical device 24A-24N, a log of caregivers 23 that used the medical device 24A-24N most recently and/or within a time period, a history of locations of the medical device 24A-24N within the medical environment 12, and a history of the usage of the medical device 24A-24N (e.g., status), which may be overlayed (e.g., as text or graphics) on the visual reconstruction 22. In some embodiments, once generated, the device indicator DI details may be generated as links that lead to additional information. For example, the device indicator DI details related to interactions with the medical devices 24A-24N by specific caregivers 23 may be selected to highlight, zoom, and/or otherwise indicate the avatar of the caregiver 23 within the visual simulation 20. Likewise, location history information of the patient 16, caregiver 23, or medical device 24A-24N may be utilized to generate additional rooms of interest 50A-50F on the visual simulation 20. In some embodiments, the selection of the avatar of the patient P, the avatar of the caregiver CG, or the device indicator DI may reconfigure the top-down schematic perspective to specific rooms 50A-50F associated with the avatar of the patient P, the avatar of the caregiver CG, or the device indicator DI.

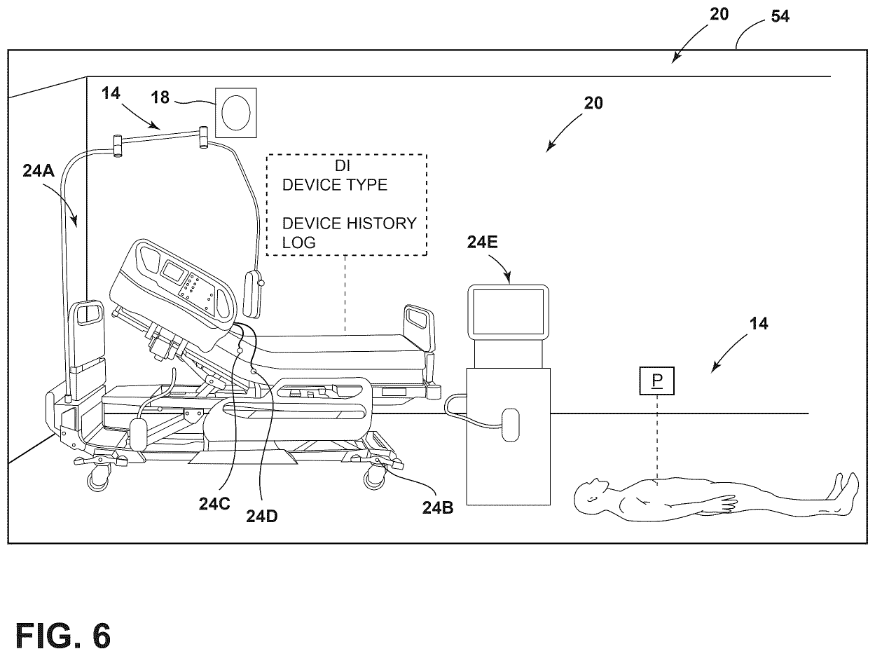

With reference now to FIG. 6, the visual simulation 20 is depicted on the display 54 of the device 56A-56C. The visual simulation 20 is generated as first-person perspective surrounding the patient 16 during the medical incident 14. The visual simulation 20 may include the visual reconstruction 22 of a medical environment 12, the avatar of the patient P, one or more avatars of caregivers CG or other personnel within the medical environment 12, caregiver identifiers CI, room indicators RI of the rooms 50A-50F, and device indicators DI of the medical devices 24A-24N. The first-person perspective of the visual reconstruction 22 of a medical environment 12 may be configured to have a perspective from the patient's point of view, the caregiver's point of view, or a free travel that allows a user to explore the visual reconstruction 22 of a medical environment 12 freely. In some embodiments, the visual reconstruction 22 of a medical environment 12 is generated to a relative scale of the dimensions of the medical environment 12. The first-person perspective may be beneficial to place a user at the scene of the medical incident 14 from the point of view of the patient 16, the caregiver 23, or free travel.

Similar to the other perspectives, the human-machine interface 58 may be shown on the visual simulation 20 of the display 54 depicted in FIG. 6 or otherwise controllable outside of the display 54 (e.g., a keyboard) and may include cursors, time controls, options to change views, the ability to select avatars of caregivers CG that are generated based on the caregiver of interest criteria or classifications, and the ability to select medical devices of interest based on the criteria described above. The first-person perspective may also be interfaceable with one or more positional sensors via movement of the display 54 or other component. In this manner, a user may obtain information about one or more of the caregivers 23 by selecting the avatar of the caregiver CG to obtain the caregiver identifier CI details (e.g., name, employment position, responsibilities, shift details, movement paths, communications, interactions with medical devices 24A-24N), which may be overlayed (e.g., as text or graphics) on the visual reconstruction 22. In some embodiments, once generated, the caregiver identifier CI details may be generated as links that lead to additional information. For example, the caregiver identifier CI details related to interactions with the medical devices 24A-24N may be selected to highlight, zoom, and/or otherwise indicate that medical device 24A-24N within the visual simulation 20. In some embodiments, the system 10 may generate the visual indicia on or proximate the avatar of the caregiver 23 in a visual simulation 20 once that caregiver 23 becomes aware of the medical incident 14. For example, as the visual simulation 20 plays, once a caregiver becomes aware of the medical incident 14, the visual indicia may be implemented as a highlight of the avatar of the caregiver 23, an exclamation point over the avatar of the caregiver 23, changing the size of the avatar of the caregiver 23, or via other visual cues.

The device indicator DI details may be generated based on the medical device of interest criteria or classifications. In this manner, a user may obtain information about one or more of the medical devices 24A-24N by selecting the device indicator DI to obtain the device indicator DI details (e.g., the type of medical device 24A-24N, a log of caregivers 23 that used the medical device 24A-24N most recently and/or within a time period, a history of locations of the medical device 24A-24N within the medical environment 12, and a history of the usage of the medical device 24A-24N (e.g., status), which may be overlayed (e.g., as text or graphics) on the visual reconstruction 22. In some embodiments, once generated, the device indicator DI details may be generated as links that lead to additional information. For example, the device indicator DI details related to interactions with the medical devices 24A-24N by specific caregivers 23 may be selected to highlight, zoom, and/or otherwise indicate the avatar of the caregiver 23 within the visual simulation 20.

The various orientational perspectives of the visual simulation 20 and visual recreation 22 may be selected by a user and toggled between orientations during the course of the playback. In this manner, a user can review the visual simulation 20 and visual recreation 22 at any desired orientational perspective throughout the review of the medical incident of 2D and 3D visualization.

With reference to FIGS. 7A-7C, the display 54 may be implemented in a number of devices 56A-56C. In some embodiments, the human-machine interface 58 and/or control system 100 is also implemented in the device 56A-56C. FIG. 7A depicts a mobile device 56A with the display 54. For example, the mobile device 56A may include a mobile phone, a tablet, a laptop, and/or other mobile computing devices. The human-machine interface 58 of the mobile device 56A may be primarily comprised of touch functions generated on the display 54. FIG. 7B depicts a computing device 56B with the display 54. For example, the computing device 56B may include a desktop computer. The human-machine interface 58 of the computing device 56B may be primarily comprised of keyboards, a mouse, and/or other mechanical or electrical inputs. In some embodiments, the human-machine interface 58 of the computing device 56B may include touch functions. FIG. 7C depicts a headset device 56C with the display 54. For example, the headset device 56C may include a virtual-reality (“VR”) headset, a semi VR headset, a semi VR headset and/or the like. The human-machine interface 58 of the headset device 56C may be primarily comprised of positional sensors in the headset device 56C, controllers (e.g., with positional sensors), keyboards, and/or the like. In some embodiments, the headset device 56C may be primarily used with the first-person perspective depicted in FIG. 6. For example, the display 54 may show the visual simulation 20 in full VR, semi VR, and/or hybrid VR. For example, the system 10 may superimpose the visual simulation 20 (e.g., the avatar of the patient P, one or more avatars of caregivers CG or other personnel within the medical environment 12, and/or the device indicators (“DI”) of the medical devices 24A-24N) over a physical location of the medical incident 14 in a hybrid-virtual reality experience.

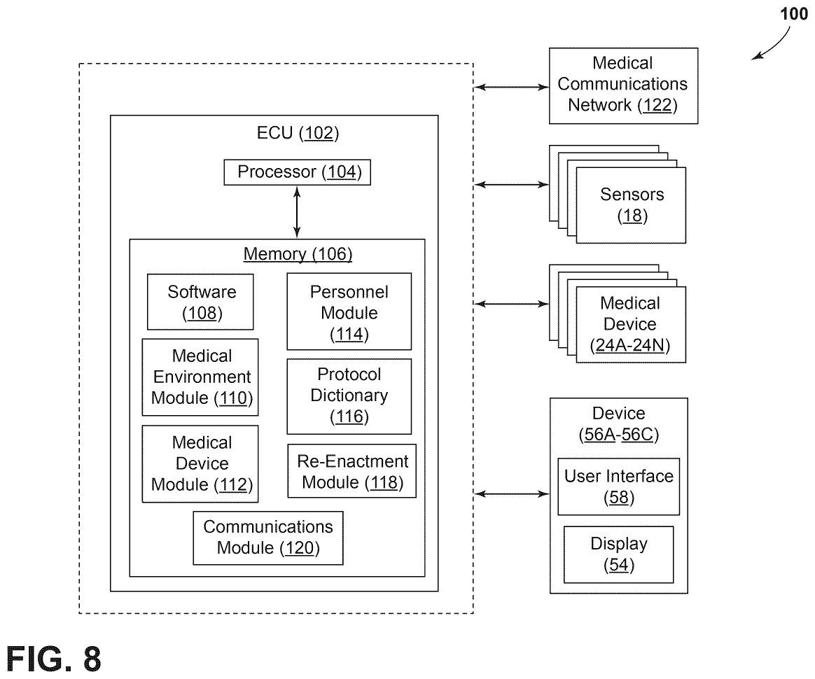

FIG. 8 illustrates the control system 100 associated with, for example, the system 10 in the medical environment 12 (e.g., the sensors 18, the medical device 24A-24N, devices 56A-56C, and other components of the system 10 and/or the medical environment 12. As will be appreciated with further reading, the control system 100 may also be associated with and/or receive instructions from a computer program product 200 that includes instructions to carry out the methods and functionalities described herein. The control system 100 may include an electronic control unit (ECU) 102. The ECU 102 may include the processor 104 and a memory 106. The processor 104 may include any suitable processor 104. Additionally, or alternatively, the ECU 102 may include any suitable number of processors, in addition to or other than the processor 104. The memory 106 may comprise a single disk or a plurality of disks (e.g., hard drives), and includes a storage management module that manages one or more partitions within the memory 106. In some embodiments, the memory 106 may include flash memory, semiconductor (solid state) memory, a database accessible via a cloud, a non-transitory storage medium, a combination thereof, and/or the like. The memory 106 may include Random Access Memory (RAM), a Read-Only Memory (ROM), or a combination thereof. The memory 106 may include at least some instructions received from the computer program product 200. The memory 106 may include instructions that, when executed by the processor 104, cause the processor 104 to, at least, perform the functions and method steps as described herein. In some embodiments, the control system 100 is a global control system in communication with a plurality of ECUs 102 (e.g., associated with the various sensors 18, medical devices 24A-24N, and/or other components of the system 10 and/or the medical environment 12. In some embodiments, the control system 100 is located in in the devices 56A-56C and receives information from the system 10 (e.g., the sensors 18 and/or medical devices 24A-24N) and the computer program product 200.

With continued reference to FIG. 8, the memory 106 may contain software 108, a medical environment module 110, a medical device module 112, a personnel module 114, a protocol dictionary 116, a re-enactment module 118, and a communications module 120. More particularly, the software 108 may be updatable instructions that operate various features of the system 10 in a remotely or locally based application. The software 108 may include instructions for generating global statistics about the system 10 or local statistics related to the medical environment 12, a branch of the medical environment, a single medical device 24A-24N, the patient 16, or the caregivers 23. In this manner, the control system 100 (e.g., the processor 104) may be configured to generate a list of several medical incidents 14 that are related to local factors (e.g., the medical environment 12, a branch of the medical environment, a single medical device 24A-24N, the patient 16, or the caregivers 23) or a list of medical incidents 14 related to several different medical environments in addition to the medical environment 12. The control system 100 (e.g., the processor 104) may generate the list of medical incidents 14 and allow a user to select individual medical incident 14 for review or obtain metadata about each of the select medical incidents 14. In some embodiments, the software 108 includes machine-learning algorithms to generate recommendations, for example, based on a finding on similarities between multiple medical incidents 14.

The medical environment module 110 may include instructions for the visual reconstruction 22 of the medical environment 12. For example, the instructions may include pre-saved models of the medical environment 12 or the dimensions, locations, and relative sizes of the medical environment 12. The medical environment module 110 may further and/or additionally include extrapolations for the dimensions, locations, and relative sizes of the medical environment 12 (e.g., through the sensors 18). In some embodiments, the medical environment module 110 may further include details of specific rooms 50A-50F, such as room numbers, which branch of the medical environment 12 the room 50A-50F is located, patients 16 assigned to the room 50A-50F, caregivers 23 assigned to the room 50A-50F, room temperature, and/or care regiments assigned to the room 50A-50F. In this manner, the medical environment module 110 permits a user of the system 10 to quickly and accurately identify various features related to one or more of the rooms 50A-50F in the visual simulation 20 through selection or automatic population on the visual simulation 20.

The medical device module 112 may include information on the location, type, and status (e.g., settings and usage logs) of the medical devices 24A-24N, administration rates (e.g., of drugs or fluids), measurements of the patient's 16 vitals, and/or the like. The medical device module 112 may receive information from the one or more sensors 18 and/or other connections to the medical devices 24A-24N. In this manner, the medical device module 112 permits a user of the system 10 to quickly and accurately identify (e.g., via generation of the device indicators DI) various features, statuses, and locations related to one or more of the medical devices 24A-24N in the visual simulation 20 through selection or automatic population on the visual simulation 20. In some embodiments, once generated, the device indicators DI details may be generated as links that lead to additional information (e.g., the caregiver identifier CI details).

The personnel module 114 may include information related to caregivers 23 surrounding the medical incident 14. More particularly, which avatars of caregivers CG to generate (e.g., caregivers of interest), such as an assigned caregiver 23, a first-on-scene caregiver 23, a last-on-scene caregiver 23, a selected caregiver 23, and/or other criteria on a case-by-case basis. The personnel module 114 may include information related to caregivers 23 surrounding the medical incident 14. The personnel module 114 may further include the caregiver identifier CI details (e.g., name, employment position, responsibilities, shift details, movement paths, communications, interactions with medical devices 24A-24N), which may be overlayed (e.g., as text or graphics) on the visual reconstruction 22. Likewise, the personnel module 114 may also include instructions related to the location and generation of the avatar of the patient P in the visual simulation 20. In some embodiments, once generated, the caregiver identifier CI details may be generated as links that lead to additional information (e.g., device indicators DI details). Likewise, in some embodiments, selecting the avatar of the patient 16 may provide links or otherwise generate the caregiver identifier CI details and/or device indicators DI details associated with the patient 16. The avatar of the patient P and the one or more avatars of caregivers CG may be color-coded or discernable through other means. For example, the avatar of the patient P may include a unique identifier (e.g., color, size, shape, graphical indicia, name) that is different than the one or more avatars of caregivers CG. Further different avatars of caregivers CG may include unique identifiers (e.g., color, size, shape, graphical indicia, names, roles, and responsibilities).

The protocol dictionary 116 may include scheduling information related to the care of the patient 16. For example, the protocol dictionary 116 may include caregiver 23 identities and responsibilities associated with the patient, medical device 24A-24N protocols and regiments associated with the patient 16, and information about the patient 16 (e.g., medical history, age, name, etc.). In this manner, the protocol dictionary 116 permits a user of the system 10 to quickly and accurately identify various information about expectations, scheduling, and/or regulatory requirements of medical care and/or a history of the patient 16 in the visual simulation 20 through selection or automatic population on the visual simulation 20.

The re-enactment module 118 may include one or more pre-saved models of the avatar of the patient P, one or more avatars of caregivers CG, the type of medical environment 12, and the visual reconstruction of the medical devices 24A-24N within the visual simulation 20. For example, the re-enactment module 118 may include specific re-enactment models for the avatar of the patient P as they traverse the medical environment 12 (e.g., simulate walking, or running within the medical environment 12), communicate with caregivers 23 (e.g., communication bubbles with or without qualifying text), eat (e.g., simulate foodstuff and eating or drinking), receive care (e.g., a heart bubble and/or a re-enactment of the care), or use a restroom (e.g., sitting on a simulated toilet). The re-enactment module 118 may further include specific re-enactment models for the one or more avatars of caregivers CG as they traverse the medical environment 12 (e.g., simulate walking, or running within the medical environment 12), communicate with the patient 16 or caregivers 23 (e.g., communication bubbles with or without qualifying text), becomes aware of the medical incident 14 (e.g., an exclamation mark over the caregiver's head), usage of medical devices 24A-24N (e.g., simulate the avatar of the caregiver CG using the reconstructed medical device 24A-24N), and/or the like. The re-enactment module 118 may further include specific re-enactment models of medical device 24A-24N (e.g., pulsating size, changing colors, and/or the like when in use).

The communications module 120 may include communications between one or more caregivers 23 associated with the medical incident 14 on a medical communication network 122. For example, the caregivers may be assigned communication devices, such as mobile phones, that allow the caregivers to communicate over the medical communication network 122 over the course of working. The medical communication network 122 may be specific to the medical environment 12 (e.g., via wireless internet or application-enabled communication process) or over one or more public or private mobile networks.

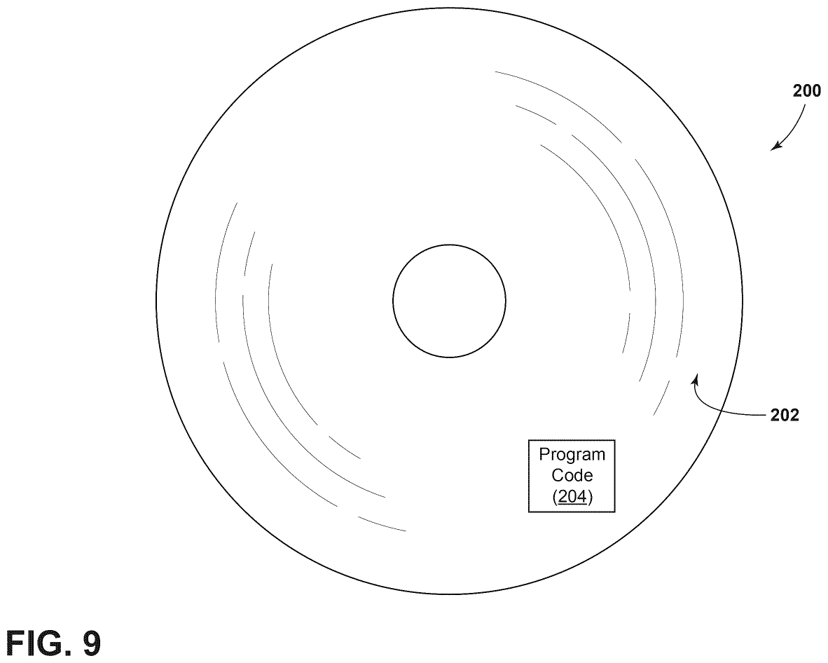

With reference now to FIG. 9, in one example, the aforementioned computer program product 200 may include many of the instructions associated with the memory 106. More particularly, the instructions included in the computer program product 200 may include instructions (e.g., saved in non-transitory memory) related to creating and generating the visual simulation 20 and linking information (e.g., the device indicators DI details and the caregiver identifier CI details). For example, the computer program product 200 may include instructions to perform the method steps and functions described herein, but may rely on certain features/inputs such as from the one or more sensors 18, the medical devices 24A-24N, the devices 56A-56C, and select or all features of the protocol dictionary 116, any pre-saved models of the medical environment 12, and select or all features of the communications module 120 (e.g., the medical communication network 122). However, in some embodiments, the computer program product 200 may include may include instructions for the system 10 to collect and store certain features/inputs such as from the one or more sensors 18, the medical devices 24A-24N, the devices 56A-56C, and select or all features of the protocol dictionary 116, any pre-saved models of the medical environment 12, and select or all features of the communications module 120 (e.g., the medical communication network 122).

The computer program product 200 may include, for instance, one or more computer-readable medium 202 (e.g., non-transitory memory) to store computer-readable program code means or logic 204 in order to provide and facilitate one or more functions and methods steps described in the present disclosure. The program code contained or stored in/on a computer-readable medium 202 can be obtained and executed by a computer, such as the control system 100 to behave/function in a particular manner. The program code can be transmitted using any appropriate medium, including (but not limited to) wireless, wireline, optical fiber, and/or radio-frequency. The program code 204 includes instructions for carrying out operations to perform, achieve, or facilitate aspects of the disclosure may be written in one or more programming languages. In some embodiments, the programming language(s) include object-oriented and/or procedural programming languages such as C, C++, C#, Java, and/or the like. The program code 204 may execute entirely on the user's device (e.g., devices 56A-56C), entirely remote from the user's computer, or a combination of partly on the user's computer and partly on a remote computer. In some embodiments, a user's computer and a remote computer are in communication via a network such as a local area network (LAN) or a wide area network (WAN), and/or via an external computer (for example, through the Internet using an Internet Service Provider).

In one example, the program code 204 includes one or more program instructions obtained for execution by one or more processors (e.g., the processor 104). The instructions contained on the program code 204 may be provided to the one or more processors of, for example, one or more computer systems (e.g., one or more of the devices 56A-56C), such that the program instructions, when executed by the one or more processors, perform, achieve, or facilitate aspects of the functionalities and methods described herein. The descriptions, figures and, flowcharts depicted and described herein illustrate the architecture, functionality, and operation of possible embodiments of system 10, methods, and/or the computer program product 200 according to an aspect of the present disclosure.

In some embodiments, as noted above, descriptions, actions, functions, figures and flowcharts depicted and described herein may represent and/or be the result of a module, segment, or portion of code, which includes one or more executable instructions for implementing the specified behaviors and/or logical functions. It should be appreciated that actions, functions, and blocks described herein may occur in a different order than depicted and/or described, or may occur simultaneous to, or partially/wholly concurrent with, one or more actions, functions, and blocks. For example, two actions or method steps (e.g., blocks) shown and/or described in succession may, in fact, be executed substantially concurrently or in the reverse order.

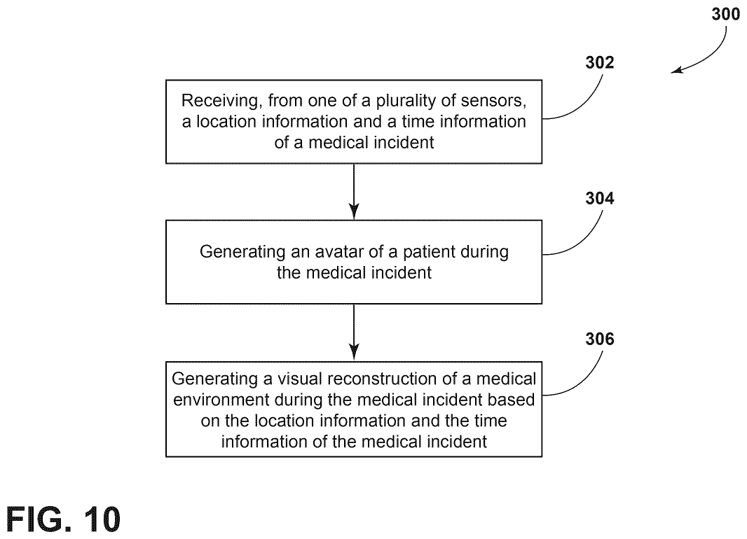

FIG. 10 illustrates a method 300 of visually generating a recreation of a medical incident associated with a patient is provided. The method 300 may be carried out utilizing a visual recreation system (e.g., the system 10) and/or a computer program (e.g., the computer program product 200). At step 302, the method 300 includes receiving, from one of a plurality of sensors, a location information and a time information of the medical incident. At step 304, the method 300 includes generating an avatar of the patient during the medical incident and, at step 306, generating a visual reconstruction of a medical environment during the medical incident based on the location information and the time information of the medical incident.

Step 304 may include, for example, generating avatars of any personnel within the visual reconstruction of the medical environment that re-enact movements within the visual reconstruction of the medical environment in a time period leading up to the medical incident. Step 304 may further include, for example, generating avatars of any personnel within the visual reconstruction of the medical environment that re-enact movements within the visual reconstruction of the medical environment in a time period after the medical incident. Step 304 may further still include, determining, from the one or more sensors or a medical communication network, when the caregivers became aware of the medical incident, and generating a visual indicia on or proximate the avatar of the caregiver in a visual simulation once they become aware. In still further embodiments, step 304 may include generating a re-enactment of the avatar of the patient during the medical incident. For example, by classifying the medical incident and selecting a re-enactment model based on the medical incident. In some embodiments, step 304 may further yet include generating an avatar of a caregiver of interest, and generating a re-enactment of the avatar of the caregiver of interest surrounding the medical incident. For example, by classifying an activity of the caregiver of interest and selecting a re-enactment model based on the activity.

Step 306 may include, for example, generating a perspective of several rooms of interest surrounding a room where the medical incident occurred in the visual reconstruction of the medical environment. In some embodiments, step 306 may further include, generating the visual reconstruction of the medical environment in at least one of a top-down perspective and an isometric perspective and scaling the perspective by enlarging rooms of interest within the medical environment.

It should be appreciated that the method 300 and any functional steps described herein may be carried out, in any order, by instructions contained in the control system 100 or the program code 204. In this manner, both the control system 100 and the computer program product 200 may include instructions for carrying out the methods, functions, and steps described throughout.

The disclosure herein may be further summarized in the following paragraphs and further characterized by combinations of any and all of the various aspects described therein.

According to one aspect of the present disclosure, a computer program product includes a non-transitory computer-readable storage medium readable by one or more processing circuits and storing instructions for execution by one or more processors for performing a method of visually generating a recreation of a medical incident associated with a patient based on feedback from one or more sensors. The method includes receiving, from the one or more sensors, a location information and a time information of the medical incident, and generating a visual simulation of the medical incident based on the location information and the time information of the medical incident.

According to another aspect, a product provides generating a visual simulation within a time window that includes at least one of a period of time before, during, or after a medical incident.

According to still another aspect, a product provides modifying a rate of a passage of time within a time window of a generated visual simulation associated with a medical incident.

According to yet another aspect, a product provides reversing the rate of the passage of time within a time window of a generated visual simulation associated with a medical incident.

According to another aspect, a product provides modifying a time window of a generated visual simulation associated with a medical incident.

According to still yet another aspect, a product provides generating an avatar of the patient in a visual simulation that reenacts a medical incident.

According to yet another aspect, a product provides generating a visual reconstruction of a medical environment surrounding a patient during a medical incident.

According to another aspect, a product provides receiving, from one or more sensors, information on an assigned caregiver's location during a medical incident, and generating, in a visual simulation, the information on the assigned caregiver's location during the medical incident.

According to still another aspect, a product provides generating an avatar of an assigned caregiver that reenacts the assigned caregiver's activities surrounding a medical incident and a visual reconstruction of a medical environment surrounding the assigned caregiver during the reenactment.

According to yet another aspect, a product provides receiving, from one or more sensors, information on a first-on-scene caregiver's location during a medical incident, and generating, in a visual simulation, the information on the first-on-scene caregiver's location during the medical incident.

According to another aspect, a product provides generating an avatar of a first-on-scene caregiver that reenacts the first-on-scene caregiver's activities surrounding a medical incident and a visual reconstruction of a medical environment surrounding the first-on-scene caregiver during the reenactment.

According to still another aspect, a product provides receiving, from one or more sensors, information on a time when a caregiver last provided an in-person status check on the patient prior to a medical incident, and generating, in a visual simulation, the information on the time when a caregiver last provided an in-person status check on the patient prior to the medical incident.

According to still yet another aspect, a product provides receiving, from a medical communication network, one or more communications between caregivers associated with a medical incident, and generating a user option to recreate the one or more communications in a visual simulation.

According to another aspect, a product provides generating a visual reconstruction of a medical environment surrounding a patient during a medical incident that includes a room where the medical incident occurred, an avatar of the patient that reenacts the medical incident, and one or more medical devices within the room.

According to still another aspect, a product provides receiving, from the one or more sensors, a status of the one or more medical devices during a medical incident, and generating a user option to recreate the status of the one or more medical devices in a visual simulation of the medical incident.

According to still another aspect, a product provides generating a visual simulation of a medical incident with a plurality of user options.

According to still another aspect, a product provides generating a user option to select a room of interest for a medical incident, visually reconstructing the room of interest if the user option is received, and generating an avatar of any caregivers in the room that reenact the caregivers' activities surrounding the medical incident.

According to still yet another aspect, a product provides generating a user option to select a caregiver of interest for a medical incident, and generating an avatar of the caregiver of interest that reenacts the caregiver of interest's activities surrounding the medical incident.

According to another aspect, a product provides receiving, from a medical communication network, one or more communications of a caregiver of interest surrounding a medical incident, and generating a user option to recreate the one or more communications in a visual simulation of the medical incident.

According to still another aspect, a product provides generating a visual reconstruction of a medical environment from an isometric perspective surrounding a patient during a medical incident.

According to another aspect, a product provides scaling an isometric perspective of a medical environment during a medical incident by enlarging rooms of interest within the medical environment.

According to still another aspect, a product provides generating a visual reconstruction of a medical environment from a top-down perspective surrounding a patient during a medical incident.

According to still yet another aspect, a product provides scaling a top-down perspective of a medical environment during a medical incident by enlarging rooms of interest within the medical environment.

According to another aspect, a product provides generating a visual reconstruction of a medical environment from a first-person perspective surrounding a patient during a medical incident.

According to still another aspect, a product provides generating a visual simulation of a medical incident on a headset.

According to another aspect, a product provides superimposing a visual simulation over a physical location of a medical incident in a hybrid-virtual reality experience.

According to another aspect of the present disclosure, a visual recreation system of visually generating a recreation of a medical incident associated with a patient is provided. The system includes a memory and a processor. The memory includes instructions that, when carried out by the processor, cause the processor to receive, from one or more sensors, a location information and a time information of the medical incident. The instructions further cause the processor to generate a visual simulation of the medical incident including an avatar of the patient and a visual reconstruction of a medical environment based on the location information and the time information of the medical incident.

According to another aspect, one or more sensors include devices carried by caregivers.

According to still another aspect, one or more sensors include sensors integrated with medical devices that obtain status information on the medical devices.

According to still yet another aspect, one or more sensors include sensors located on at least one of walls and ceiling of a medical environment that obtain location information of a patient involved in a medical incident.

According to yet another aspect, a processor is configured to generate a visual reconstruction of a medical environment from one of a first-person perspective, an isometric perspective, a schematic perspective, and a top-down perspective surrounding the patient during the medical incident.

According to another aspect, a processor is configured to generate a visual reconstruction of a medical environment from a first-person perspective surrounding a patient during a medical incident.

According to still another aspect, a processor is configured to superimpose at least part of a visual simulation over a physical location of a medical incident in a hybrid-virtual reality experience.

According to another aspect, a processor is configured to generate a visual simulation of a medical incident with a plurality of user options.

According to still another aspect, a visual reconstruction of a medical environment includes a perspective of several rooms of interest surrounding a room where the medical incident occurred.

According to still yet another aspect, a processor is configured to generate a user option to select a room of interest for the medical incident, and enlarge the room of interest if the user option is received.

According to yet another aspect, a processor is configured to determine if a caregiver is proximate the room of interest or is a caregiver of interest, and generate an avatar of the caregiver that reenacts the caregiver's activities surrounding a medical incident.

According to another aspect, a processor is configured to determine if a caregiver is present in the room of interest, and, if a caregiver is present, generate an avatar of the caregiver that reenacts the caregiver's activities surrounding a medical incident.

According to still another aspect, a processor is configured to generate a user option to select a caregiver of interest, and generate an avatar of the caregiver that reenacts the caregiver's activities surrounding a medical incident.

According to still yet another aspect, a processor is configured to receive, from a medical communication network, one or more communications by a caregiver of interest, and generate a user option to recreate the one or more communications in a visual simulation of a medical incident.

According to another aspect, a processor is configured to generate a time stamp in a visual simulation of a medical incident of when a caregiver last provided an in-person status check on the patient prior to the medical incident.

According to still another aspect, a processor is configured to generate a time stamp in a visual simulation of when a patient last requested assistance from a caregiver.

According to yet another aspect of the present disclosure, a method of visually generating a recreation of a medical incident associated with a patient is provided. The method includes receiving, from one or more sensors, a location information and a time information of the medical incident, and generating an avatar of the patient during the medical incident and a visual reconstruction of a medical environment during the medical incident based on the location information and the time information of the medical incident.

According to still yet another aspect, a method includes generating a perspective of several rooms of interest surrounding a room where a medical incident occurred in a visual reconstruction of a medical environment.

According to another aspect, a method includes generating avatars of any personnel within a visual reconstruction of a medical environment that re-enact movements within a visual reconstruction of the medical environment in a time period leading up to a medical incident in the medical environment.

According to still another aspect, a method includes generating avatars of any personnel within a visual reconstruction of a medical environment that re-enact movements within the visual reconstruction of the medical environment in a time period after a medical incident in the medical environment.

According to another aspect, a method includes generating avatars of any caregivers within a visual reconstruction of a medical environment that re-enact movements within the visual reconstruction of the medical environment.

According to still another aspect, a method includes determining, from the one or more sensors or a medical communication network, when a caregivers became aware of the medical incident.

According to still yet another aspect, a method includes generating a visual indicia on or proximate an avatar of a caregiver in a visual simulation once the caregiver became aware of a medical incident.

According to another aspect, a method includes generating a re-enactment of an avatar of the patient during a medical incident.

According to still another aspect, a method includes classifying a medical incident and selecting a re-enactment model based on the medical incident.

According to still yet another aspect, a method includes generating an avatar of a caregiver of interest.

According to another aspect, a method includes classifying an activity of a caregiver of interest and selecting a re-enactment model based on the activity.

According to still another aspect, a method includes generating a visual reconstruction of a medical environment associated with a medical incident in at least one of a top-down perspective and an isometric perspective.

According to another aspect, a method includes scaling a perspective by enlarging rooms of interest within a medical environment associated with a medical incident.

It will be understood by one having ordinary skill in the art that construction of the described disclosure and other components is not limited to any specific material. Other exemplary embodiments of the disclosure disclosed herein may be formed from a wide variety of materials, unless described otherwise herein.

For purposes of this disclosure, the term “coupled” (in all of its forms, couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature or may be removable or releasable in nature unless otherwise stated.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

It is also important to note that the construction and arrangement of the elements of the disclosure, as shown in the exemplary embodiments, is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts, or elements shown as multiple parts may be integrally formed, the operation of the interfaces may be reversed or otherwise varied, the length or width of the structures and/or members or connector or other elements of the system may be varied, the nature or number of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any described processes or steps within described processes may be combined with other disclosed processes or steps to form structures within the scope of the present disclosure. The exemplary structures and processes disclosed herein are for illustrative purposes and are not to be construed as limiting.

What is claimed is:

1. A computer program product comprising:
a non-transitory computer-readable storage medium readable by one or more processing circuit and storing instructions for execution by one or more processor for performing a method of visually generating a recreation of a medical incident associated with a patient based on feedback from one or more sensors, comprising:
receiving, from the one or more sensors, a location information and a time information of the medical incident; and
generating a visual simulation of the medical incident based on the location information and the time information of the medical incident.

2. The product according to claim 1, further including generating the visual simulation within a time window that includes at least one of a period of time before, during, or after the medical incident.

3. The product according to claim 2, further including modifying a rate of a passage of time within the time window.

4. The product according to claim 3, further including reversing the rate of the passage of time within the time window.

5. The product according to claim 2, further including modifying the time window.

6. The product according to claim 1, further including generating an avatar of the patient in the visual simulation that reenacts the medical incident.

7. The product according to claim 6, further including generating a visual reconstruction of a medical environment surrounding the patient during the medical incident.

8. The product according to claim 1, further including:
receiving, from the one or more sensors, an information on an assigned caregiver's location during the medical incident; and
generating, in the visual simulation, the information on the assigned caregiver's location during the medical incident.

9. The product according to claim 8, further including generating an avatar of the assigned caregiver that reenacts the assigned caregiver's activities surrounding the medical incident and a visual reconstruction of a medical environment surrounding the assigned caregiver during the reenactment.

10. The product according to claim 1, further including:
receiving, from the one or more sensors, information on a first-on-scene caregiver's location during the medical incident; and
generating, in the visual simulation, the information on the first-on-scene caregiver's location during the medical incident.

11. The product according to claim 10, further including generating an avatar of the first-on-scene caregiver that reenacts the first-on-scene caregiver's activities surrounding the medical incident and a visual reconstruction of a medical environment surrounding the first-on-scene caregiver during the reenactment.

12. The product according to claim 1, further including:
receiving, from the one or more sensors, information on a time when a caregiver last provided an in-person status check on the patient prior to the medical incident; and
generating, in the visual simulation, the information on the time when a caregiver last provided an in-person status check on the patient prior to the medical incident.

13. The product according to claim 1, further including:
receiving, from a medical communication network, one or more communications between caregivers associated with the medical incident; and
generating a user option to recreate the one or more communications in the visual simulation.

14. The product according to claim 1, further including:
generating a visual reconstruction of a medical environment surrounding the patient during the medical incident that includes a room where the medical incident occurred, an avatar of the patient that reenacts the medical incident, and one or more medical devices within the room.

15. The product according to claim 14, further including:
receiving, from the one or more sensors, a status of the one or more medical devices during the medical incident; and
generating a user option to recreate the status of the one or more medical devices in the visual simulation.

16. A visual recreation system of visually generating a recreation of a medical incident associated with a patient, the system comprising:
a memory and a processor, the memory including instructions that, when carried out by the processor, cause the processor to:
receive, from the one or more sensors, a location information and a time information of the medical incident; and
generate a visual simulation of the medical incident including an avatar of the patient and a visual reconstruction of a medical environment based on the location information and the time information of the medical incident.

17. The visual recreation system according to claim 16, wherein the processor is further configured to generate a visual reconstruction of a medical environment from one of a first-person perspective, an isometric perspective, a schematic perspective, and a top-down perspective surrounding the patient during the medical incident.

18. The visual recreation system according to claim 16, wherein the processor is further configured to:
determine if a caregiver is proximate the room of interest of identify a caregiver of interest; and
generate an avatar of the caregiver that reenacts the caregiver's activities surrounding the medical incident.

19. A method of visually generating a recreation of a medical incident associated with a patient, the method comprising:
receiving, from one or more sensors, a location information and a time information of the medical incident; and
generating an avatar of the patient during the medical incident and a visual reconstruction of a medical environment during the medical incident based on the location information and the time information of the medical incident.

20. The method according to claim 19, further including generating avatars of any personnel within the visual reconstruction of the medical environment that re-enact movements within the visual reconstruction of the medical environment in a time surrounding the medical incident.
